(19) United States
(12) Patent Application Publication
(10) Pub. No.: US 2025/0246517 A1
(43) Pub. Date: Jul. 31, 2025

(54) MULTI-ZONE IMPINGEMENT COOLING OF SEMICONDUCTOR DEVICES

(71) Applicant: Taiwan Semiconductor Manufacturing Company, Ltd., Hsinchu (TW)

(72) Inventors: Tsunyen WU, Hsinchu County (TW); Singda JIANG, Taichung City (TW); Shih-Wei LIU, Chiayi City (TW); Kathy Wei YAN, Hsinchu (TW); Jun HE, Zhubei City (TW)

(73) Assignee: Taiwan Semiconductor Manufacturing Company, Ltd., Hsinchu (TW)

(21) Appl. No.: 18/771,901

(22) Filed: Jul. 12, 2024

Related U.S. Application Data
(60) Provisional application No. 63/626,317, filed on Jan. 29, 2024.

(51) Int. Cl. H01L 23/473; H01L 25/065

(52) U.S. Cl. CPC H01L 23/473; H01L 25/0655

(57) ABSTRACT

The present disclosure describes a system with multi-zone impingement cooling of a semiconductor device. The system includes a first die and a second die on a substrate, a heat transfer structure, and a controller. The heat transfer structure includes a first compartment disposed over the first die, a second compartment disposed over the second die and separate from the first compartment, a first inlet pipe connected to the first compartment and configured to supply a first liquid coolant to the first compartment, and a second inlet pipe connected to the second compartment and configured to supply a second liquid coolant to the second compartment. The controller is configured to control a first flow rate of the first liquid coolant based on a temperature of the first die and a second flow rate of the second liquid coolant based on a temperature of the second die.

### CROSS-REFERENCE TO RELATED APPLICATION

This application claims the benefit of U.S. Provisional Patent Application No. 63/626,317, titled “A Multizone Impingement Cooling Thermal Solution,” filed Jan. 29, 2024, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (FinFETs), gate-all-around field effect transistors (GAAFETs), complementary field effect transistors (CFETs), nanosheet transistors, nanowire transistors, multi-bridge channel transistors, nano-ribbon transistors, and other similar structured transistors. Additionally, multiple dies can be packaged on a substrate to improve device performance. Such scaling down has increased the complexity of semiconductor manufacturing and packaging processes and increased the testing difficulty of the semiconductor devices.

### BRIEF DESCRIPTION OF THE DRAWINGS

Aspects of the present disclosure are best understood from the following detailed description when read with the accompanying figures.

FIGS. 1, 2, 5, 6, 12, and 13 illustrate partial cross-sectional views of a system with multi-zone impingement cooling of a semiconductor device, in accordance with some embodiments.

FIGS. 3, 4, and 7-11 illustrate partial top-down views of a system with multi-zone impingement cooling of a semiconductor device, in accordance with some embodiments.

FIG. 14 is a flow diagram of a method for multi-zone impingement cooling of a semiconductor device, in accordance with some embodiments.

FIG. 15 illustrates an example computer system in which various embodiments of the present disclosure can be implemented.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. Additionally, multiple dies including various devices, such as logic dies and memory dies, can be packaged on a substrate to improve device performance. The continuous scaling down of device dimensions and the increasing demand for device performance may require various process improvements, which can have multiple challenges. For example, a semiconductor device can generate heat during operation, which can increase the temperature of the dies in the semiconductor device. A microchannel cold plate or a heatsink can be placed on the semiconductor device to remove the heat and lower the temperature of the dies. However, different dies of the semiconductor device on the same substrate may generate different amounts of heat and operate at different preferred ranges of temperature. For example, a logic die may generate more heat and operate at a preferred temperature range from about 85° C. to about 105° C. A memory die may generate less heat and operate at a preferred temperature range from about 65° C. to about 90° C. With a single microchannel cold plate or a single heatsink for all the dies on the same substrate, different dies may operate at a same temperature, which may not be in the preferred temperate range of every die. As a result, the dies operating outside of their preferred temperature ranges may have reduced device performance and the testing time of all the dies in the semiconductor device may increase. Additionally, a thermal interface material may be required between the dies and the microchannel cold plate or the heatsink for heat conductance. The quality and performance of the thermal interface material can limit the cooling capability of the microchannel cold plate and the heatsink.

Various embodiments in the present disclosure provide systems and methods for multi-zone impingement cooling of a semiconductor device or a semiconductor package. In some embodiments, a system can include a semiconductor device, a heat transfer structure on the semiconductor device, and a controller configured to control a temperature of the semiconductor device with the heat transfer structure. The semiconductor device can include a first die and a second die on a substrate. The heat transfer structure can include a first compartment over the first die and a second compartment over the second die and separate from the first compartment. A first inlet plumbing pipe can be connected to the first compartment and configured to inject a first liquid coolant onto the first die in the first compartment. A second inlet plumbing pipe can be connected to the second compartment and configured to inject a second liquid coolant onto the second die in the second compartment. The controller can be configured to control a first flow rate of the first liquid coolant based on a temperature of the first die and a second flow rate of the second liquid coolant based on a temperature of the second die. With the multi-zone impingement cooling, temperatures of the first and second dies can be separately controlled, which can improve device performance of each die and can reduce testing time of the semiconductor device. Additionally, with direct impingement of liquid coolant on the first and second dies and no thermal interface material, the heat transfer efficiency of the heat transfer structure can be improved and the cooling capability of the system can be increased.

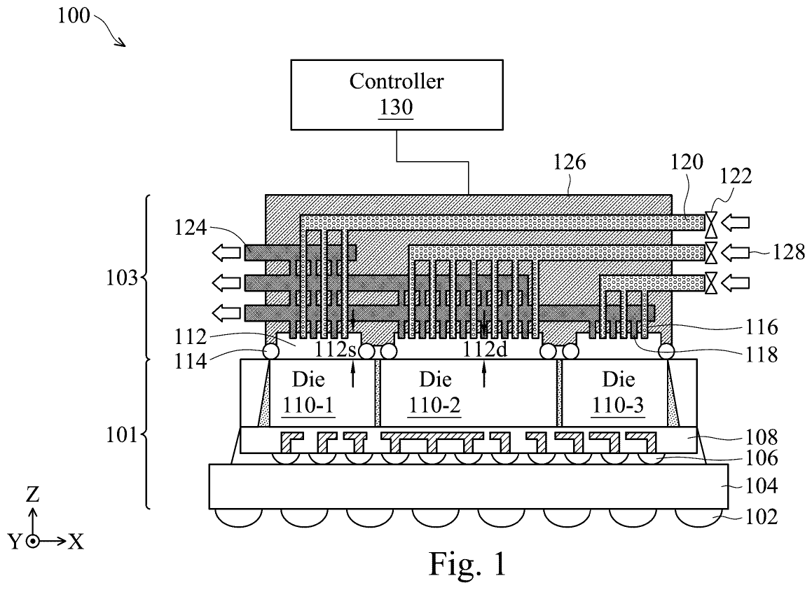

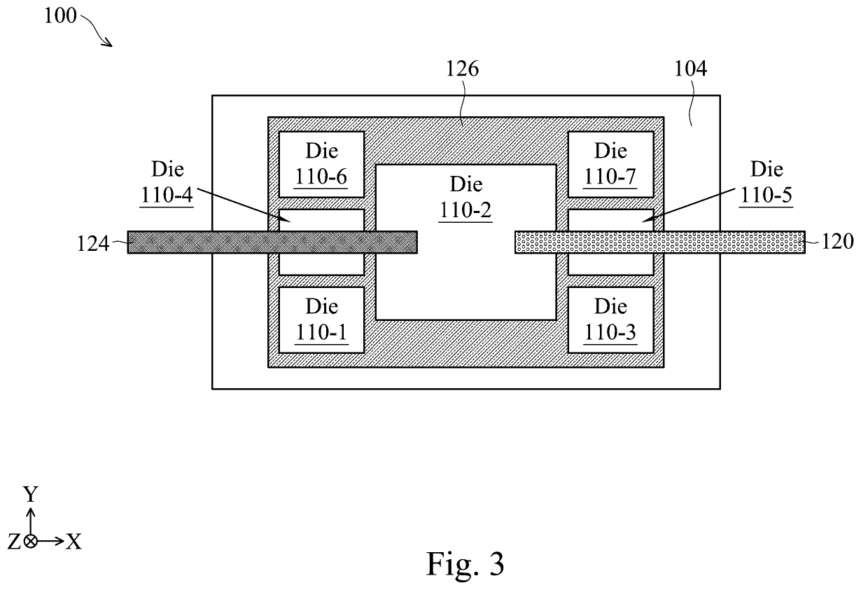

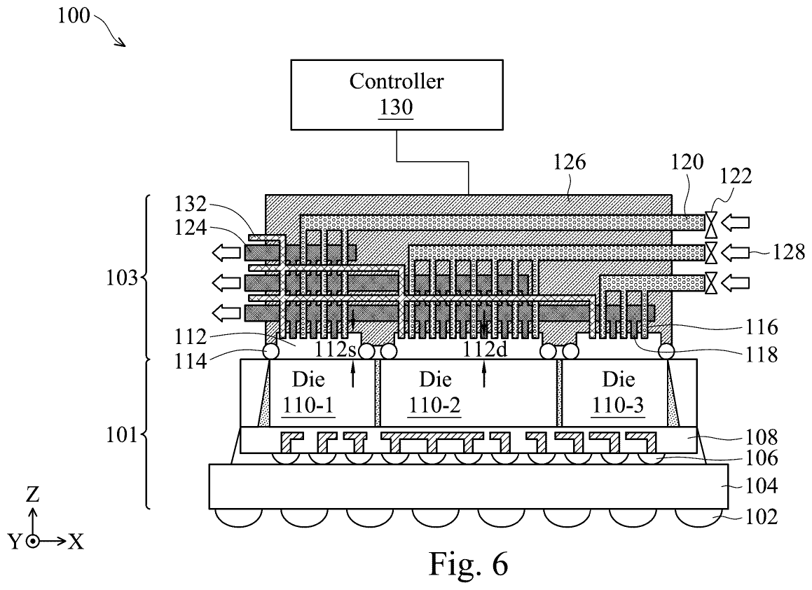

FIGS. 1, 2, 5, 6, 12, and 13 illustrate partial cross-sectional views of various embodiments of a system 100 with multi-zone impingement cooling of a semiconductor device, in accordance with some embodiments. FIGS. 3, 4, and 7-11 illustrate partial top-down views of various embodiments of system 100 with multi-zone impingement cooling of a semiconductor device, in accordance with some embodiments. In some embodiments, as shown in FIGS. 1-13, system 100 can include a semiconductor device 101, a heat transfer structure 103, and a controller 130. In some embodiments, system 100 can be configured to test semiconductor device 101 cooled by heat transfer structure 103 during a testing process. In some embodiments, semiconductor device 101 and heat transfer structure 103 can be packaged together in a semiconductor package. The discussion of elements of semiconductor device 101 and heat transfer structure 103 in FIGS. 1-13 with the same annotations applies to each other, unless mentioned otherwise. And like reference numerals generally indicate identical, functionally similar, and/or structurally similar elements.

In some embodiments, semiconductor device 101 can include dies 110-1 to 110-7, as shown in FIGS. 1-13. In some embodiments, each of dies 110-1 to 110-7 can be a logic die, a high bandwidth memory (HBM) die, or other suitable dies. In some embodiments, each of dies 110-1 and 110-3 to 110-7 can be a HBM die and die 110-2 can be a logic die. Though FIGS. 1-13 show seven dies in semiconductor device 101, semiconductor device 101 can have any number of dies. In addition, semiconductor device 101 can be included in a semiconductor package.

Referring to FIGS. 1-13, semiconductor device 101 can further include external connectors 102, substrate 104, conductive connectors 106, and interposer 108. In some embodiments, external connectors 102 can be disposed on a bottom side of substrate 104. In some embodiments, external connectors 102 can include ball grid array (BGA) connectors, solder balls, metal pillars, controlled collapse chip connection (C4) bumps, micro bumps, or other suitable connectors. In some embodiments, external connectors 102 can include a conductive material, such as solder, copper, aluminum, gold, nickel, silver, palladium, tin, and a combination thereof. In some embodiments, external connectors 102 can include a solder-free conductive material. In some embodiments, external connectors 102 can be used to physically and electrically connect substrate 104 to other external devices, packages, connecting components, and the like.

In some embodiments, substrate 104 can include a printed circuit board (PCB) or the like. In some embodiments, substrate 104 can include electrical connectors (not shown) formed on opposite sides of substrate 104. The electrical connectors on the opposite sides can be electrically inter-coupled through metal lines and vias (not shown) inside substrate 104. The electrical connectors, metal lines, and metal vias on substrate 104 can electrically connect a single component on one side of substrate 104 to another component on an opposite side of substrate 104. For example, substrate 104 can electrically connect dies 110-1 to 110-7 through interposer 108 and conductive connectors 106 on a top side of substrate 104 to an external component through external connectors 102 on the bottom side of substrate 104. In some embodiments, substrate 104 can provide mechanical support for components packaged on substrate 104, such as dies 110-1 to 110-7, conductive connectors 106, interposer 108, and/or heat transfer structure 103.

In some embodiments, conductive connectors 106 can be disposed on the top side of substrate 104. In some embodiments, conductive connectors 106 can include C4 bumps, micro bumps, BGA connectors, solder balls, metal pillars, or other suitable connectors. In some embodiments, external connectors 102 and conductive connectors 106 can include a same connector or different connectors. In some embodiments, conductive connectors 106 can include a conductive material, such as solder, copper, aluminum, gold, nickel, silver, palladium, tin, and a combination thereof. In some embodiments, conductive connectors 106 can include a solder-free conductive material. In some embodiments, external connectors 102 and conductive connectors 106 can include a same conductive material or different conductive materials. In some embodiments, conductive connectors 106 can be used to physically and electrically connect dies 110-1 to 110-7 to substrate 104 through interposer 108.

In some embodiments, interposer 108 can bond dies 110-1 to 110-7 to conductive connectors 106 on substrate 104. In some embodiments, interposer 108 can provide electric connection routing, power distribution, and other suitable functions. For example, interposer 108 can electrically connected dies 110-1 to 110-7 to conductive connectors 106 and subsequently external components on the bottom side of substrate 104. In some embodiments, interposer 108 can include redistribution circuit structures, through vias, conductive connectors, and other suitable components, which are not shown in detail for clarity.

In some embodiments, as shown in FIGS. 1-4, heat transfer structure 103 can include impingement compartments 112, seals 114, inlet nozzles 116, outlet nozzles 118, a manifold 126, inlet plumbing pipes 120, control valves 122, outlet plumbing pipes 124, and a liquid coolant 128. In some embodiments, heat transfer structure 103 can be placed on semiconductor device 101 to cool dies 110-1 to 110-7. In some embodiments, liquid coolant 128 can be delivered to impingement compartments 112 above dies 110-1 to 110-7 through control valves 122, inlet plumbing pipes 120, and inlet nozzles 116. Liquid coolant 128 can remove heat generated from dies 110-1 to 110-7 through outlet nozzles 118 and outlet plumbing pipes 124. In some embodiments, liquid coolant 128 can include water, liquid nitrogen, or other suitable liquid coolant. In some embodiments, manifold 126 can provide physical support and connections to inlet plumbing pipes 120 and outlet plumbing pipes 124. In some embodiments, manifold 126 can include metal, plastic, or other suitable materials.

In some embodiments, each of impingement compartments 112 can be disposed over each of dies 110-1 to 110-7. In some embodiments, impingement compartments 112 can hold liquid coolant 128 between dies 110-1 to 110-7 and inlet and outlet nozzles 116 and 118. In some embodiments, impingement compartments 112 can have a space 112s along a Z-axis above top surfaces of dies 110-1 to 110-7 for liquid coolant 128. In some embodiments, space 112s can range from about 0.5 mm to about 2 mm. In some embodiments, impingement compartments 112 above different dies may have different space 112s based on heat generated from dies 110-1 to 110-7. If space 112s is less than about 0.5 mm, heat generated from dies 110-1 to 110-7 may not be removed efficiently and dies 110-1 to 110-7 may not operate at their preferred temperature ranges. If space 112s is greater than about 2 mm, heat transfer efficiency may not be further improved but manufacturing cost may increase.

In some embodiments, a seal 114 can surround each impingement compartment 112 to seal liquid coolant 128 between corresponding impingement compartments 112 and dies 110-1 to 110-7. In some embodiments, seals 114 can be removable. In some embodiments, seals 114 can include rubber or other suitable materials. In some embodiments, controller 130 can control motors (not shown) in heat transfer structure 103 to move heat transfer structure 103 towards semiconductor device 101, apply a force on seals 114, and seal liquid coolant 128 inside impingement compartments 112, thus avoiding leakage of liquid coolant 128.

In some embodiments, inlet nozzles 116 and outlet nozzles 118 can be disposed inside impingement compartments 112 above dies 110-1 to 110-7. Controller 130 can control inlet nozzles 116 to inject liquid coolant 128 directly on the top surfaces of dies 110-1 to 110-7. Controller 130 can control additional control valves (not shown) on outlet pumping pipes 124 to remove liquid coolant 128 in impingement compartments 112 through outlet nozzles 118 and outlet pumping pipes 124. In some embodiments, a distance 112d along a Z-axis between the top surfaces of dies 110-1 to 110-7 and inlet and outlet nozzles 116 and 118 can range from about 0.1 to about 2 mm. If distance 112d is less than about 0.1 mm, heat generated from dies 110-1 to 110-7 may not be removed efficiently and dies 110-1 to 110-7 may not operate at their preferred temperature ranges. If distance 112d is greater than about 2 mm, heat transfer efficiency may not be further improved but manufacturing cost may increase. In some embodiments, a ratio between distance 112d and space 112s can range from about 0.5 to about 1 to balance the pressure drop and flow uniformity of liquid coolant 128. If the ratio is less than about 0.5, the pressure drop may increase, which can require a larger pump to circulate liquid coolant 128 and can reduce the structure reliability of heat transfer structure 103. If the ratio is greater than about 1, the injected liquid coolant 128 may be non-uniform, which can limit the cooling capability of liquid coolant 128. In some embodiments, inlet and outlet nozzles 116 and 118 above different dies may have different distance 112d based on heat generated from dies 110-1 to 110-7. In some embodiments, distance 112d of inlet nozzles 116 and outlet nozzles 118 in a same impingement compartment 112 can be separately controlled. In some embodiments, the dimensions of inlet nozzles 116 and outlet nozzles 118 can depend on the physical design of heat transfer structure 103. In some embodiments, a length of inlet nozzles 116 and outlet nozzles 118 can range from about 0.1 mm to about 1 mm. In some embodiments, a diameter of inlet nozzles 116 and outlet nozzles 118 can range from about 0.1 mm to about 1 mm. In some embodiments, a distance between inlet nozzles 116 and outlet nozzles 118, which can be referred to herein as “an inlet/outlet pitch,” can range from about 0.5 mm to about 2 mm to balance the pressure drop and flow uniformity of liquid coolant 128. In some embodiments, a ratio between the inlet/outlet pitch to the diameter can range from about 2 to about 5. If the ratio is less than about 2, the pressure drop of liquid coolant 128 may increase. If the ratio is greater than about 5, the flow uniformity of liquid coolant 128 may be reduced and the thermal resistance of heat transfer structure 103 may increase.

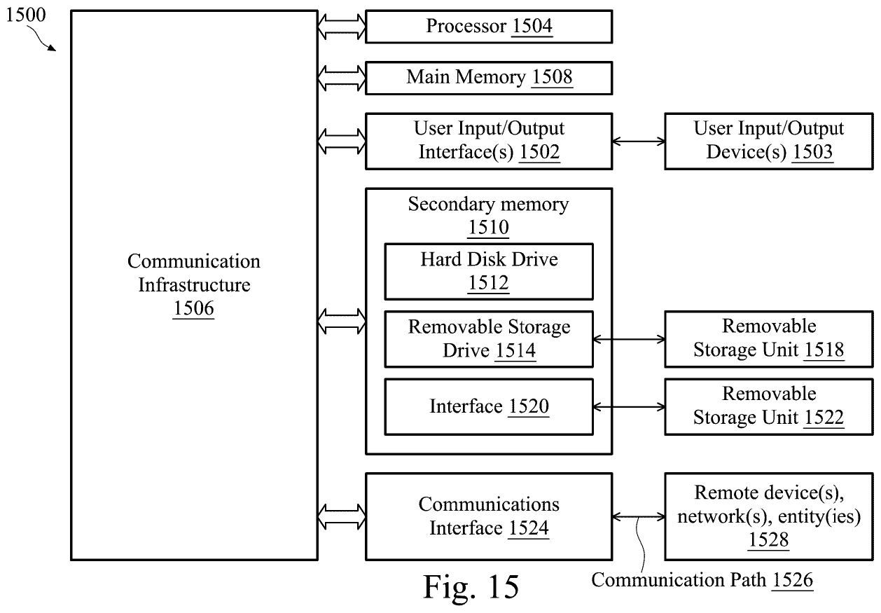

In some embodiments, each impingement compartment 112 can be connected to a single inlet plumbing pipe 120. Inlet plumbing pipes 120 can deliver liquid coolant 128 to each of impingement compartments 112. In some embodiments, each inlet plumbing pipe 120 can have a single control valve 122 to control a flow rate of liquid coolant 128. In some embodiments, controller 130 can be connected to semiconductor device 101 and heat transfer structure 103 to control the operation and temperature of dies 110-1 to 110-7. An embodiment of controller 130 is described in detail in FIG. 15. In some embodiments, each of dies 110-1 to 110-7 can include a temperature sensor (not shown) and controller 130 can obtain the temperatures of dies 110-1 to 110-7 from the temperature sensors. In some embodiments, controller 130 can control the flow rates of liquid coolant 128 in inlet plumbing pipes 120 with control valves 122. In some embodiments, controller 130 can adjust the flow rate in each inlet plumbing pipe 120 based on the temperature for each of dies 110-1 to 110-7. For example, die 110-1 can have a first temperature and die 110-2 can have a second temperature different from the first temperature. Based on the first and second temperatures and the preferred temperature ranges of dies 110-1 and 110-2, controller 130 can adjust a first flow rate of liquid coolant 128 supplied to die 110-1 and a second flow rate of liquid coolant 128 supplied to die 110-2. In some embodiments, the first flow rate can be different from the second flow rate.

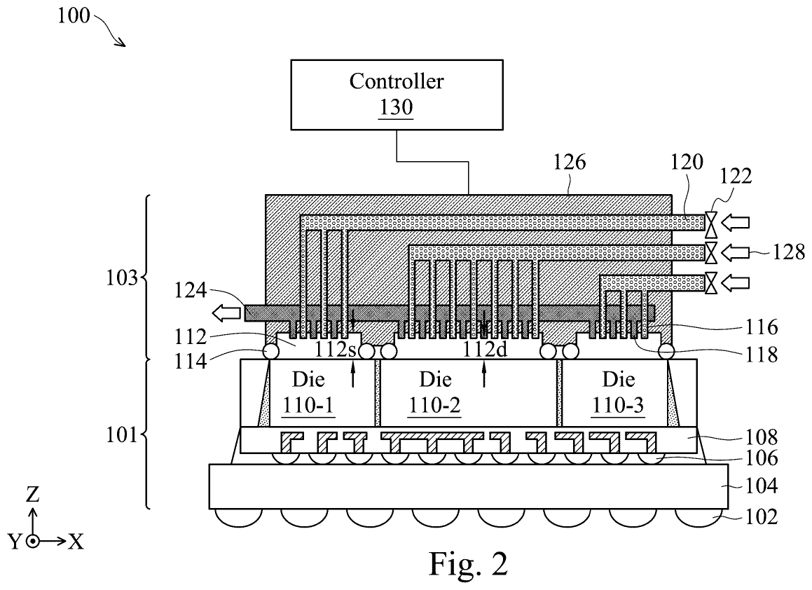

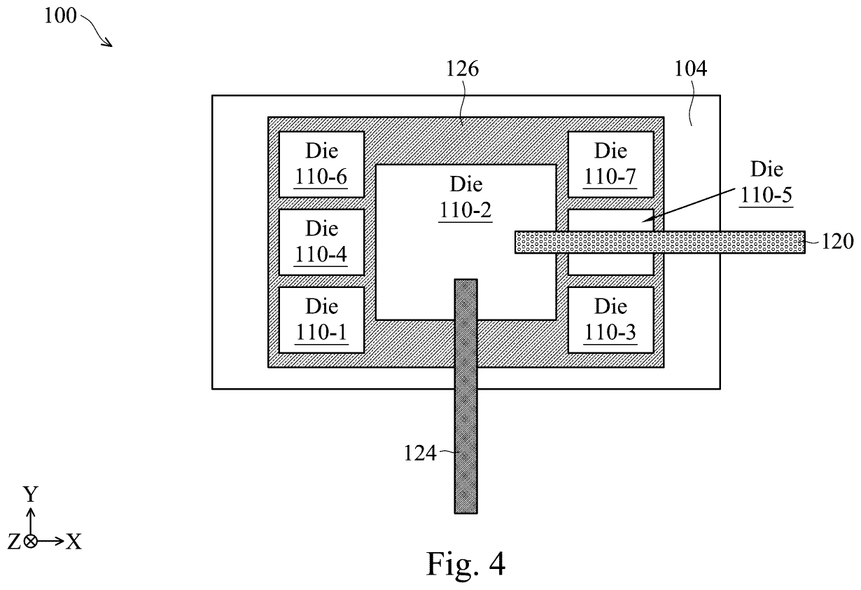

In some embodiments, as shown in FIG. 1, each impingement compartment 112 can be connected to a single outlet plumbing pipe 124. Outlet plumbing pipes 124 can remove liquid coolant 128 from each of impingement compartments 112. In some embodiments, as shown in FIG. 2, all impingement compartments 112 can be connected to a single outlet plumbing pipe 124 to remove liquid coolant 128. In some embodiments, as shown in FIG. 3, inlet plumbing pipes 120 can be arranged in parallel with outlet plumbing pipes 124. Inlet plumbing pipes 120 can extend over a first side (e.g., right side) of substrate 104 and outlet plumbing pipes 124 can extend over a second side (e.g., left side) of substrate 104 opposite to the first side. In some embodiments, as shown in FIG. 4, inlet plumbing pipes 120 can be arranged perpendicular to outlet plumbing pipes 124. Inlet plumbing pipes 120 can extend over a first side (e.g., right side) of substrate 104 and outlet plumbing pipes 124 can extend over a second side (e.g., lower side) of substrate 104 adjacent to the first side.

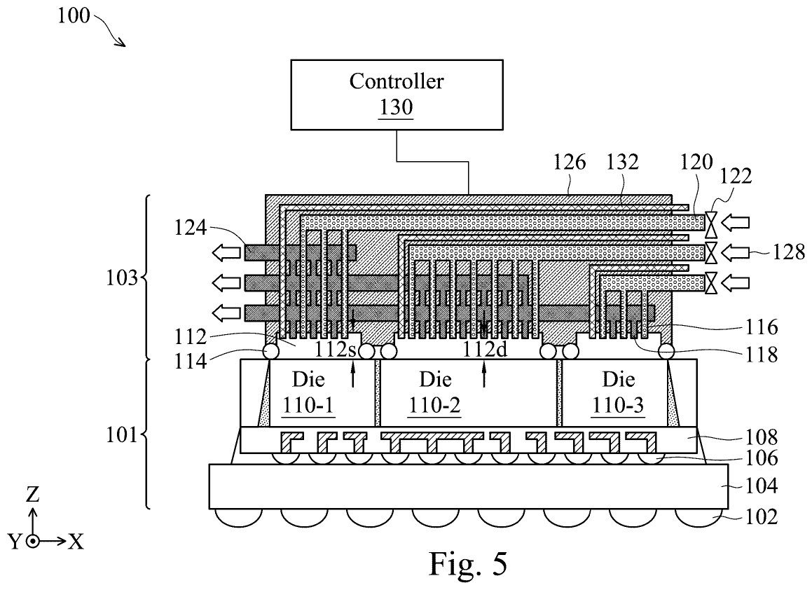

In some embodiments, as shown in FIGS. 5-11, heat transfer structure 103 can further include evacuation plumbing pipes 132. In some embodiments, each impingement compartment 112 can be connected to a single evacuation plumbing pipe 132. Evacuation plumbing pipes 132 can evacuate the air in impingement compartments 112, lower the pressure in impingement compartments 112, and thus reduce the boiling point of liquid coolant 128 in impingement compartments 112. In some embodiments, with a low pressure in impingement compartments 112, the heat generated from dies 110-1 to 110-7 can be removed by both liquid and gas phases of liquid coolant 128. In some embodiments, controller 130 can adjust the pressure in impingement compartments 112 with evacuation plumbing pipes 132 to improve heat transfer efficiency.

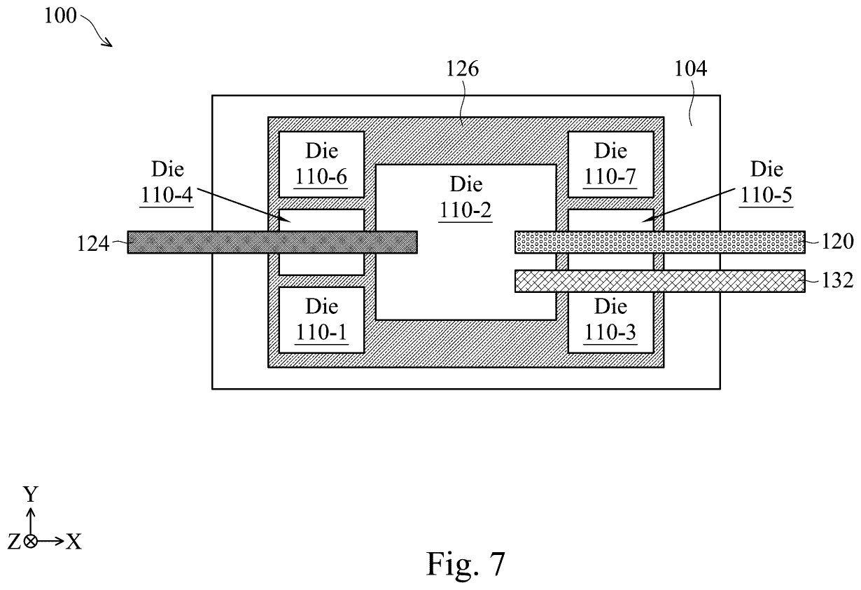

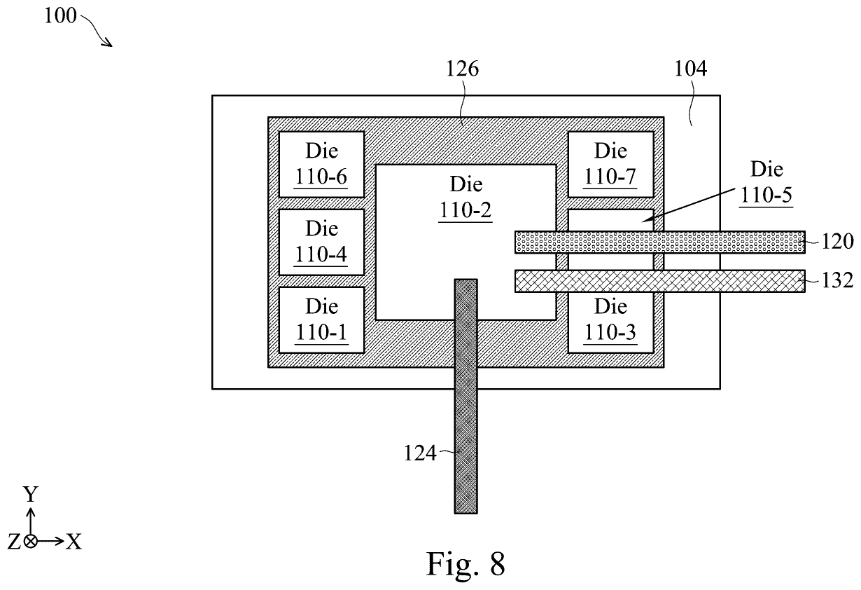

In some embodiments, as shown in FIGS. 5, 7, and 8, evacuation plumbing pipes 132 can be arranged in parallel with and adjacent to inlet plumbing pipes 120. In some embodiments, as shown in FIGS. 5 and 7, outlet plumbing pipes 124 can be arranged in parallel with inlet plumbing pipes 120. Inlet plumbing pipes 120 and evacuation plumbing pipes 132 can extend over a first side (e.g., right side) of substrate 104 and outlet plumbing pipes 124 can extend over a second side (e.g., left side) of substrate 104 opposite to the first side. In some embodiments, as shown in FIG. 8, outlet plumbing pipes 124 can be arranged perpendicular to inlet plumbing pipes 120. Inlet plumbing pipes 120 and evacuation plumbing pipes 132 can extend over a first side (e.g., right side) of substrate 104 and outlet plumbing pipes 124 can extend over a second side (e.g., lower side) of substrate 104 adjacent to the first side.

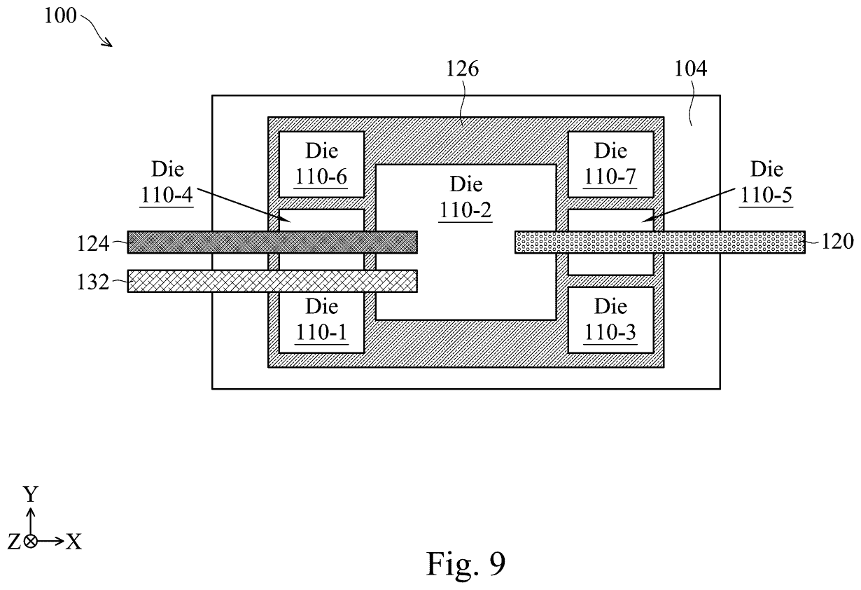

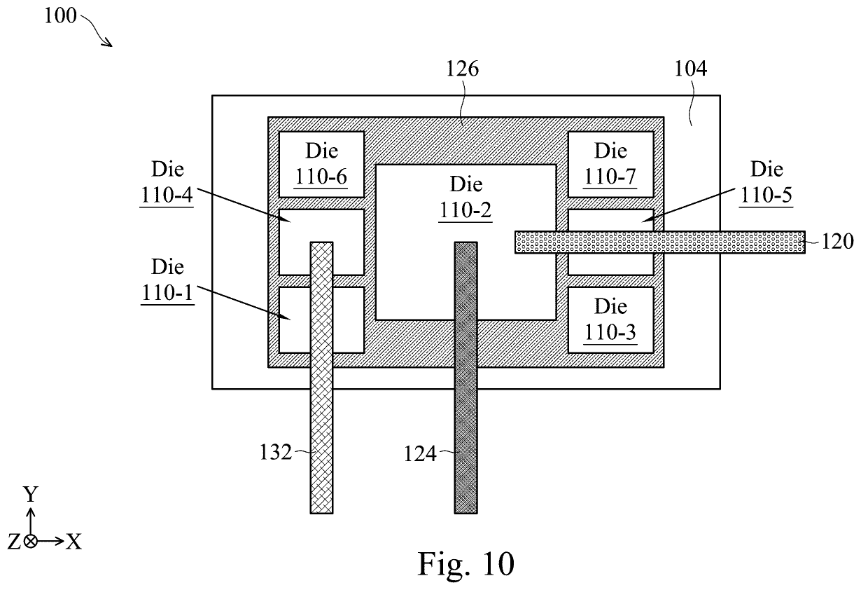

In some embodiments, as shown in FIGS. 9 and 10, evacuation plumbing pipes 132 can be arranged in parallel with and adjacent to outlet plumbing pipes 124. In some embodiments, as shown in FIG. 9, inlet plumbing pipes 120 can be arranged in parallel with outlet plumbing pipes 124. Inlet plumbing pipes 120 can extend over a first side (e.g., right side) of substrate 104 and outlet plumbing pipes 124 and evacuation plumbing pipes 132 can extend over a second side (e.g., left side) of substrate 104 opposite to the first side. In some embodiments, as shown in FIG. 10, inlet plumbing pipes 120 can be arranged perpendicular to outlet plumbing pipes 124. Inlet plumbing pipes 120 can extend over a first side (e.g., right side) of substrate 104 and outlet plumbing pipes 124 and evacuation plumbing pipes 132 can extend over a second side (e.g., lower side) of substrate 104 adjacent to the first side.

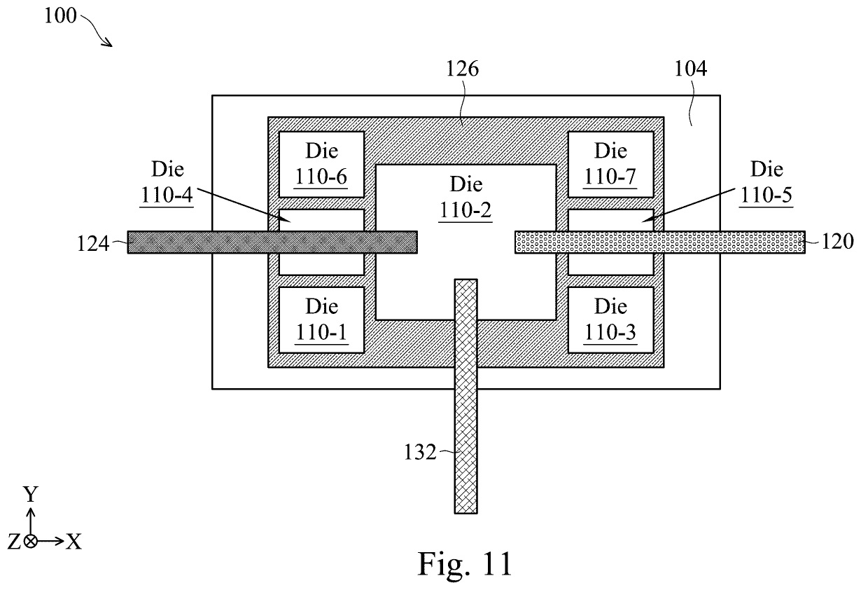

In some embodiments, as shown in FIG. 11, evacuation plumbing pipes 132 can be arranged perpendicular to inlet plumbing pipes 120 and outlet plumbing pipes 124. As shown in FIG. 11, inlet plumbing pipes 120 can extend over a first side (e.g., right side) of substrate 104, outlet plumbing pipes 124 can extend over a second side (e.g., left side) of substrate 104 opposite to the first side, and evacuation plumbing pipes 132 can extend over a third side (e.g., lower side) of substrate 104 adjacent to the first and second sides. In some embodiments, evacuation plumbing pipes 132 can be combined with inlet plumbing pipes 120. Accordingly, inlet plumbing pipes 120 can first be used to vacuum the air in impingement compartments 112 and then be used to deliver liquid coolant 128 to impingement compartments 112. In some embodiments, evacuation plumbing pipes 132 can be combined with outlet plumbing pipes 124. Accordingly, outlet plumbing pipes 124 can first be used to vacuum the air in impingement compartments 112 and then be used to remove liquid coolant 128 from impingement compartments 112.

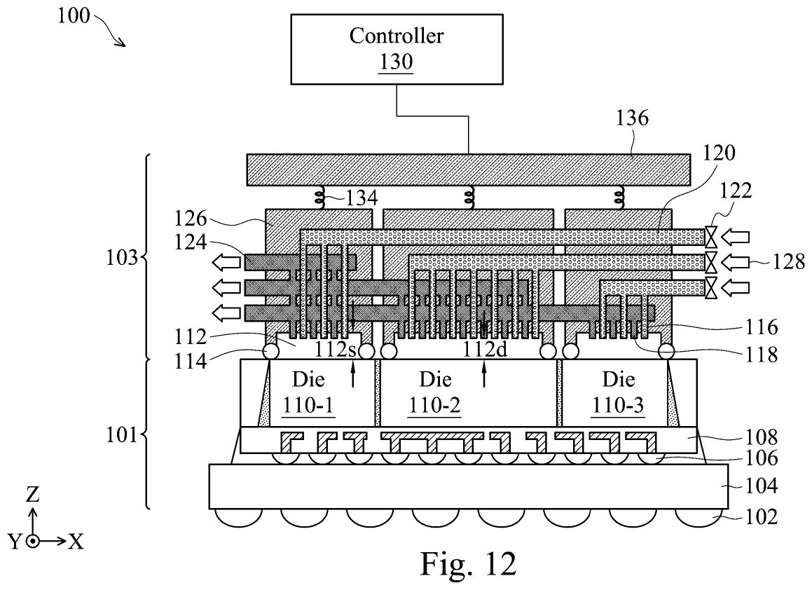

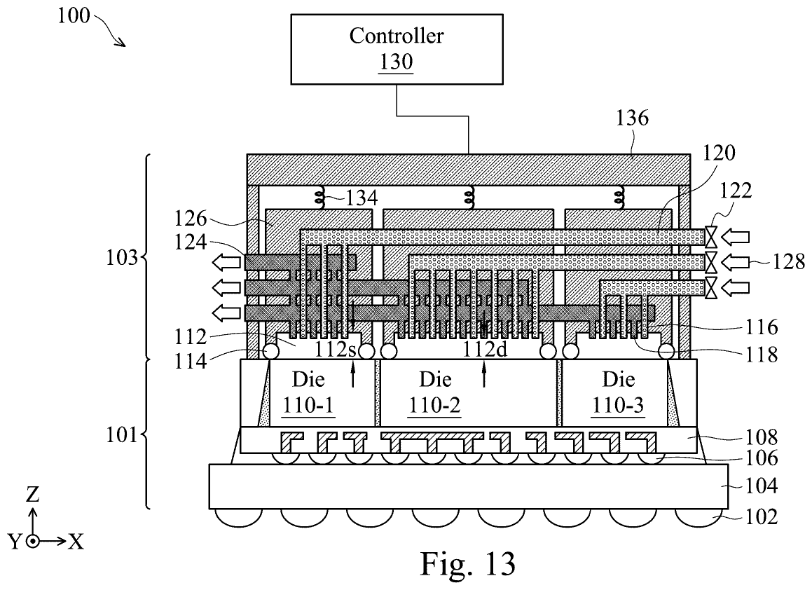

In some embodiments, as shown in FIGS. 12 and 13, heat transfer structure 103 can further include a housing structure 136 above manifolds 126 and springs 134 connecting housing structure 136 to manifolds 126. In some embodiments, as shown in FIG. 12, each of dies 110-1 to 110-7 can have a single manifold 126 disposed thereon. Each manifold 126 can be connected to housing structure 136 through a single spring 134. With springs 134 on manifolds 126, suitable forces can be applied to each of manifolds 126 to improve the seal between impingement compartments 112 and dies 110-1 to 110-7, thus avoiding leakage of liquid coolant 128. In some embodiments, as shown in FIG. 13, housing structure 136 can include additional structures (e.g., legs or covers) extending around manifolds 126. In some embodiments, the additional structures can support and protect manifolds 126, inlet plumbing pipes 120, and outlet plumbing pipes 124. In some embodiments, the additional structures may or may not be in contact with semiconductor device 101. In some embodiments, one of manifolds 126 can be disposed on a local hot spot of dies 110-1 to 110-7 to improve heat transfer efficiency.

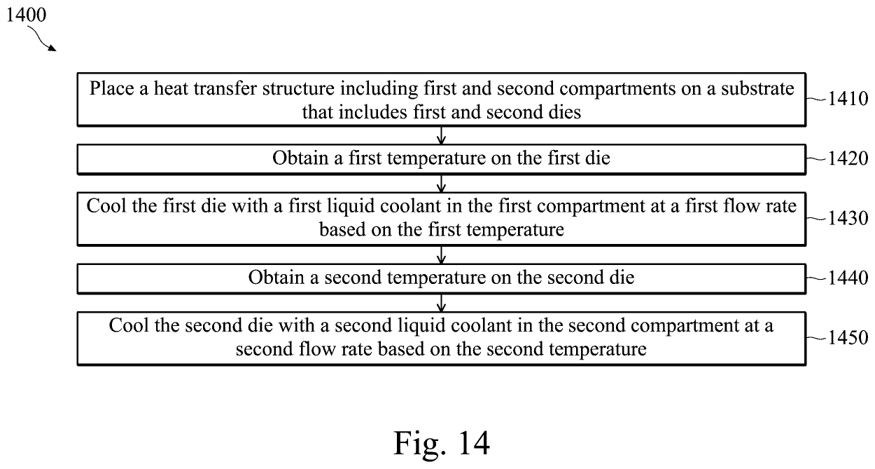

FIG. 14 is a flow diagram of a method 1400 for multi-zone impingement cooling of semiconductor device 101, in accordance with some embodiments. Method 1400 may not be limited to semiconductor device 101 and can be applicable to other devices that would benefit from the multi-zone impingement cooling. Additional operations may be performed between various operations of method 1400 and may be omitted merely for clarity and ease of description. Additional operations can be provided before, during, and/or after method 1400; one or more of these additional operations are briefly described herein. Moreover, not all operations may be needed to perform the disclosure provided herein. Additionally, some of the operations may be performed simultaneously or in a different order than shown in FIG. 14. In some embodiments, one or more other operations may be performed in addition to or in place of the presently-described operations. For illustrative purposes, the operations illustrated in FIG. 14 will be described with reference to the example embodiments as illustrated in FIGS. 1-13.

In referring to FIG. 14, method 1400 begins with operation 1410 and the process of placing a heat transfer structure including first and second impingement compartments on a substrate including first and second dies. The first compartment can be placed over the first die and the second compartment can be placed over the second die. For example, as shown in FIGS. 1-13, controller 130 can control the motors (not shown) in heat transfer structure 103 to move and place heat transfer structure 103 on substrate 104. Substrate 104 can include dies 110-1 to 110-7. Heat transfer structure 103 can include impingement compartments 112, each of which can be placed over each of dies 110-1 to 110-7. In some embodiments, heat transfer structure 103 can be placed by the motors controlled by controller 130 on semiconductor device 101 during testing of semiconductor device 101. For example, controller 130 can control a pick and place (PnP) arm (not shown) to put semiconductor device 101 in a testing socket (not shown). Controller 130 can control the motors to move heat transfer structure 103 to the testing socket and place heat transfer structure 103 on semiconductor device 101. A force can be applied to heat transfer structure 103 to avoid leaking of liquid coolant 128. Controller 130 can open valves 122 and deliver liquid coolant 128 to impingement compartments 112 above each of dies 110-1 to 110-7. Dies 110-1 to 110-7 can generate heat after semiconductor device 101 starts operating or testing. In some embodiments, heat transfer structure 103 and semiconductor device 101 can be packaged in a semiconductor package and heat transfer structure 103 can be placed on top of semiconductor device 101.

Referring to FIG. 14, in operation 1420, a first temperature on the first die is obtained. For example, as shown in FIGS. 1-13, controller 130 can obtain a temperature of die 110-1. In some embodiments, die 110-1 can include a temperature sensor (not shown) to measure the temperature of die 110-1 during operation. In some embodiments, controller 130 can obtain the temperature of die 110-1 from the temperature sensor. In some embodiments, the temperature sensor can measure a temperature profile across a top surface of die 110-1 with a distribution of local hot spots and controller 130 can obtain the temperature profile. In some embodiments, instead of directly obtaining the temperature of die 110-1, controller 130 can obtain the power level of die 110-1 and generate the temperature of die 110-1 based on the power level.

Referring to FIG. 14, in operation 1430, the first die is cooled with a first liquid coolant in the first compartment at a first flow rated based on the first temperature. For example, as shown in FIGS. 1-13, die 110-1 can be cooled by liquid coolant 128 in impingement compartment 112 disposed thereon. Based on the temperature of die 110-1, controller 130 can control a first flow rate of liquid coolant 128 delivered to die 110-1 with control valves 122. Liquid coolant 128 in impingement compartment 112 can remove the heat generated by die 110-1 during operation or testing and keep the temperature of die 110-1 at a preferred temperature or a preferred temperature range. For example, a logic die can operate at a preferred temperature range from about 85° C. to about 105° C. A memory die can operate at a preferred temperature range from about 65° C. to about 90° C.

In some embodiments, as shown in FIGS. 5-11, heat transfer structure 103 can further include evacuation plumbing pipes 132 and impingement compartment 112 above die 110-1 can be connected to a single evacuation plumbing pipe 132. Evacuation plumbing pipes 132 can evacuate the air in impingement compartments 112, lower the pressure in impingement compartments 112, and thus reduce the boiling point of liquid coolant 128 in impingement compartments 112. In some embodiments, with a lower pressure in impingement compartments 112, the heat generated from die 110-1 can be removed by both liquid and gas phases of liquid coolant 128. In some embodiments, controller 130 can adjust the pressure in impingement compartment 112 with evacuation plumbing pipe 132 to improve heat transfer efficiency. In some embodiments, as shown in FIGS. 1-13, space 112s of impingement compartments 112 and distance 112d between the top surfaces of dies 110-1 to 110-7 and inlet and outlet nozzles 116 and 118 can be adjusted to further improve heat transfer efficiency.

Referring to FIG. 14, in operation 1440, a second temperature on the second die is obtained. For example, as shown in FIGS. 1-13, controller 130 can obtain a temperature of die 110-2. In some embodiments, die 110-2 can include a temperature sensor (not shown) to measure the temperature of die 110-2 during operation. In some embodiments, controller 130 can obtain the temperature of die 110-2 from the temperature sensor. In some embodiments, the temperature sensor can measure a temperature profile across a top surface of die 110-2 with a distribution of local hot spots and controller 130 can obtain the temperature profile. In some embodiments, instead of directly obtaining the temperature of die 110-2, controller 130 can obtain the power level of die 110-2 and generate the temperature of die 110-2 based on the power level.

Referring to FIG. 14, in operation 1450, the second die is cooled with a second liquid coolant in the second compartment at a second flow rated based on the second temperature. For example, as shown in FIGS. 1-13, die 110-2 can be cooled by liquid coolant 128 in impingement compartment 112 disposed thereon. Based on the temperature of die 110-2, controller 130 can control a second flow rate of liquid coolant 128 delivered to die 110-2 with control valves 122. Liquid coolant 128 in impingement compartment 112 can remove the heat generated by die 110-2 during operation or testing and keep the temperature of die 110-2 at a preferred temperature or a preferred temperature range. For example, a logic die can operate at a preferred temperature range from about 85° C. to about 105° C. A memory die can operate at a preferred temperature range from about 65° C. to about 90° C. In some embodiments, die 110-1 can be a memory die and die 110-2 can be a logic die. The preferred temperatures and preferred temperature ranges for dies 110-1 and 110-2 can be different. Accordingly, the second flow rate of liquid coolant 128 delivered to die 110-2 can be different from the first flow rate of liquid coolant 128 delivered to die 110-1. In some embodiments, to further lower the temperature of die 110-2 after reaching a maximum flow rate of liquid coolant 128 delivered to die 110-2, controller 130 can continue adjusting the first flow rate of liquid coolant 128 delivered to die 110-1. Lowering the temperature of die 110-1 adjacent to die 110-2 can further lower the temperature of die 110-2. Similarly, the temperature of die 110-1 can be further lowered after reaching a maximum flow rate of liquid coolant 128 delivered to die 110-1.

In some embodiments, similar to die 110-1, as shown in FIGS. 5-11, impingement compartment 112 above die 110-2 can be connected to a single evacuation plumbing pipe 132 to improve heat transfer efficiency. In some embodiments, as shown in FIGS. 1-13, space 112s of impingement compartments 112 and distance 112d between the top surfaces of dies 110-1 to 110-7 and inlet and outlet nozzles 116 and 118 can be adjusted to further improve heat transfer efficiency. In some embodiments, with the adjustment of control valves 122, space 112s, and distance 112d, the temperatures of dies 110-1 to 110-7 can be actively controlled during the testing or operating process. With the temperatures of dies 110-1 to 110-7 being separately controlled in respective preferred temperate ranges, device performance of dies 110-1 to 110-7 can be improved and the testing time of semiconductor device 101 can be reduced.

In some embodiments, after the testing of semiconductor device 101, valves 122 can be closed. Liquid coolant 128 remaining in impingement compartments 112 can be removed by a vacuum operation. Heat transfer structure 103 can be lifted from semiconductor device 101 and semiconductor device 101 can be removed from the test socket for further operation. These operations are not described in detail for clarity.

FIG. 15 is an illustration of an example computer system 1500 in which various embodiments of the present disclosure can be implemented, according to some embodiments. Computer system 1500 can be any well-known computer capable of performing the functions and operations described herein. For example, and without limitation, computer system 1500 can be capable of controlling heat transfer structure 103 for multi-zone impingement cooling of dies 110 during the testing of semiconductor device 101. Computer system 1500 can be an example of controller 130, for example, to execute one or more operations in method 1400, which describes an example method for multi-zone impingement cooling of dies 110-1 to 110-7 during the testing of semiconductor device 101.

Computer system 1500 includes one or more processors (also called central processing units, or CPUs), such as a processor 1504. Processor 1504 is connected to a communication infrastructure or bus 1506. Computer system 1500 also includes input/output device(s) 1503, such as monitors, keyboards, pointing devices, etc., that communicate with communication infrastructure or bus 1506 through input/output interface(s) 1502. A system control tool can receive instructions to implement functions and operations described herein—e.g., method 1400 of FIG. 14—via input/output device(s) 1503. Computer system 1500 also includes a main or primary memory 1508, such as random access memory (RAM). Main memory 1508 can include one or more levels of cache. Main memory 1508 has stored therein control logic (e.g., computer software) and/or data. In some embodiments, the control logic (e.g., computer software) and/or data can include one or more of the operations described above with respect to method 1400 of FIG. 14.

Computer system 1500 can also include one or more secondary storage devices or memory 1510. Secondary memory 1510 can include, for example, a hard disk drive 1512 and/or a removable storage device or drive 1514. Removable storage drive 1514 can be a floppy disk drive, a magnetic tape drive, a compact disk drive, an optical storage device, tape backup device, and/or any other storage device/drive.

Removable storage drive 1514 can interact with a removable storage unit 1518. Removable storage unit 1518 includes a computer usable or readable storage device having stored thereon computer software (control logic) and/or data. Removable storage unit 1518 can be a floppy disk, magnetic tape, compact disk, DVD, optical storage disk, and/or any other computer data storage device. Removable storage drive 1514 reads from and/or writes to removable storage unit 1518 in a well-known manner.

In some embodiments, secondary memory 1510 can include other means, instrumentalities or other approaches for allowing computer programs and/or other instructions and/or data to be accessed by computer system 1500. Such means, instrumentalities or other approaches can include, for example, a removable storage unit 1522 and an interface 1520. Examples of the removable storage unit 1522 and the interface 1520 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, secondary memory 1510, removable storage unit 1518, and/or removable storage unit 1522 can include one or more of the operations described above with respect to method 1400 of FIG. 14.

Computer system 1500 can further include a communication or network interface 1524. Communication interface 1524 enables computer system 1500 to communicate and interact with any combination of remote devices, remote networks, remote entities, etc. (individually and collectively referenced by reference number 1528). For example, communication interface 1524 can allow computer system 1500 to communicate with remote devices 1528 over communications path 1526, which can be wired and/or wireless, and which can include any combination of LANs, WANs, the Internet, etc. Control logic and/or data can be transmitted to and from computer system 1500 via communication path 1526.

The operations in the preceding embodiments can be implemented in a wide variety of configurations and architectures. Therefore, some or all of the operations in the preceding embodiments—e.g., method 1400 of FIG. 14—can be performed in hardware, in software or both. In some embodiments, a tangible apparatus or article of manufacture including a tangible computer useable or readable medium having control logic (software) stored thereon is also referred to herein as a computer program product or program storage device. This includes, but is not limited to, computer system 1500, main memory 1508, secondary memory 1510 and removable storage units 1518 and 1522, as well as tangible articles of manufacture embodying any combination of the foregoing. Such control logic, when executed by one or more data processing devices (such as computer system 1500), causes such data processing devices to operate as described herein.

Various embodiments in the present disclosure provide systems and methods for multi-zone impingement cooling of semiconductor device 101. In some embodiments, system 100 can include semiconductor device 101, heat transfer structure 103 on semiconductor device 101, and controller 130 configured to control a temperature of semiconductor device 101 with heat transfer structure 103. Semiconductor device 101 can include first die 110-1 and second die 110-2 on substrate 104. Heat transfer structure 103 can include first compartment 112 over first die 110-1 and second compartment 112 over second die 110-2 and separate from first compartment 112. First inlet plumbing pipe 120 can be connected to first compartment 112 and configured to inject liquid coolant 128 onto first die 110-1 in first compartment 112. Second inlet plumbing pipe 120 can be connected to second compartment 112 and configured to inject liquid coolant 128 onto second die 110-2 in second compartment 112. Controller 130 can be configured to control a first flow rate of liquid coolant 128 based on a temperature of first die 110-1 and a second flow rate of liquid coolant 128 based on a temperature of the second die 110-2. With the multi-zone impingement cooling, temperatures of first and second dies 110-1 and 110-2 can be separately controlled, which can improve device performance of each die and can reduce testing time of semiconductor device 101. Additionally, with direct impingement of liquid coolant 128 on first and second dies 110-1 and 110-2 and no thermal interface material, the heat transfer efficiency of heat transfer structure 103 can be improved and the cooling capability of system 100 can be increased.

In some embodiments, a system includes a first die and a second die on a substrate, a heat transfer structure, and a controller. The heat transfer structure includes a first compartment disposed over the first die, a second compartment disposed over the second die and separate from the first compartment, a first inlet pipe connected to the first compartment and configured to supply a first liquid coolant to the first compartment, and a second inlet pipe connected to the second compartment and configured to supply a second liquid coolant to the second compartment. The controller is configured to control a first flow rate of the first liquid coolant based on a temperature of the first die and a second flow rate of the second liquid coolant based on a temperature of the second die.

In some embodiments, a heat transfer structure includes a first compartment disposed over a first die, a first inlet pipe connected to the first compartment and configured to supply a first liquid coolant to the first compartment, a second compartment disposed over a second die and separate the first compartment, and a second inlet pipe connected to the second compartment and configured to supply a second liquid coolant to the second compartment.

In some embodiments, a method includes placing a heat transfer structure on a substrate. The substrate includes a first die and a second die. The heat transfer structure includes a first compartment over the first die and a second compartment over the second die. The method further includes obtaining a first temperature of the first die, cooling the first die with a first liquid coolant in the first compartment at a first flow rate based on the first temperature, obtaining a second temperature on the second die, and cooling the second die with a second liquid coolant in the second compartment at a second flow rate based on the second temperature. The second flow rate is different from the first flow rate.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a first die and a second die on a substrate;
a heat transfer structure comprising:
a first compartment disposed over the first die;
a second compartment disposed over the second die and separate from the first compartment;
a first inlet pipe connected to the first compartment and configured to supply a first liquid coolant to the first compartment; and
a second inlet pipe connected to the second compartment and configured to supply a second liquid coolant to the second compartment; and
a controller configured to control a first flow rate of the first liquid coolant based on a temperature of the first die and a second flow rate of the second liquid coolant based on a temperature of the second die.

2. The system of claim 1, further comprising:
a first valve on the first inlet pipe and configured to control the first flow rate of the first liquid coolant; and
a second valve on the second inlet pipe and configured to control the second flow rate of the second liquid coolant, wherein the second flow rate is different from the first flow rate.

3. The system of claim 1, further comprising:
a first nozzle connected to the first inlet pipe and configured to inject the first liquid coolant in the first compartment and onto the first die; and
a second nozzle connected to the second inlet pipe and configured to inject the second liquid coolant in the second compartment and onto the second die.

4. The system of claim 1, further comprising:
a first outlet pipe connected to the first compartment and configured to remove the first liquid coolant from the first compartment; and
a second outlet pipe connected to the second compartment and configured to remove the second liquid coolant from the second compartment.

5. The system of claim 4, wherein:
the first inlet pipe is parallel with the first outlet pipe;
the second inlet pipe is parallel with the second outlet pipe;
the first and second inlet pipes extend over a first side of the substrate; and
the first and second outlet pipes extend over a second side of the substrate opposite to the first side.

6. The system of claim 4, wherein:
the first inlet pipe is perpendicular to the first outlet pipe;
the second inlet pipe is perpendicular to the second outlet pipe;
the first and second inlet pipes extend over a first side of the substrate; and
the first and second outlet pipes extend over a second side of the substrate adjacent to the first side.

7. The system of claim 1, further comprising:
a first removable seal surrounding the first compartment and configured to seal the first liquid coolant between the first compartment and the first die; and
a second removable seal surrounding the second compartment and configured to seal the second liquid coolant between the second compartment and the second die.

8. The system of claim 1, further comprising:
a first evacuation pipe connected to the first compartment and configured to adjust a first pressure in the first compartment; and
a second evacuation pipe connected to the second compartment and configured to adjust a second pressure in the second compartment.

9. The system of claim 8, wherein:
the first inlet pipe is parallel with the first evacuation pipe; and
the second inlet pipe is parallel with the second evacuation pipe.

10. The system of claim 8, wherein:
the first inlet pipe is perpendicular to the first evacuation pipe; and
the second inlet pipe is perpendicular to the second evacuation pipe.

11. The system of claim 1, wherein the first and second liquid coolants comprise water.

12. The system of claim 1, further comprising a housing structure, a first spring connecting the first compartment to the housing structure, and a second spring connecting the second compartment to the housing structure.

13. A heat transfer structure, comprising:
a first compartment disposed over a first die;
a first inlet pipe connected to the first compartment and configured to supply a first liquid coolant to the first compartment;
a second compartment disposed over a second die and separate the first compartment; and
a second inlet pipe connected to the second compartment and configured to supply a second liquid coolant to the second compartment.

14. The heat transfer structure of claim 13, further comprising:
a nozzle connected to the first inlet pipe and configured to inject the first liquid coolant in the first compartment and onto the first die, wherein:
the first compartment has a space above the first die,
the nozzle and the first die is separated by a distance, and
a ratio between the distance and the space ranges from about 0.5 to about 1.

15. The heat transfer structure of claim 13, further comprising:
a first nozzle connected to the first inlet pipe and configured to inject the first liquid coolant in the first compartment and onto the first die;
a first outlet pipe connected to the first compartment and configured to remove the first liquid coolant from the first compartment; and
a second nozzle connected to the first outlet pipe and configured to remove the first liquid coolant, wherein a pitch between the first nozzle and the second nozzle ranges from about 0.5 mm to about 2 mm.

16. The heat transfer structure of claim 15, wherein the first and second nozzles have a diameter, and wherein a ratio between the diameter and the pitch ranges from about 2 to about 5.

17. A method, comprising:
placing a heat transfer structure on a substrate, wherein:
the substrate comprises a first die and a second die; and
the heat transfer structure comprises a first compartment over the first die and a second compartment over the second die;
obtaining a first temperature of the first die;
cooling the first die with a first liquid coolant in the first compartment at a first flow rate based on the first temperature;
obtaining a second temperature on the second die; and
cooling the second die with a second liquid coolant in the second compartment at a second flow rate based on the second temperature, wherein the second flow rate is different from the first flow rate.

18. The method of claim 17, further comprising controlling the first flow rate with a first valve and the second flow rate with a second valve.

19. The method of claim 17, wherein cooling the first die with the first liquid coolant comprises:
opening a first valve on a first inlet pipe connected to the first compartment to deliver the first liquid coolant;
injecting the first liquid coolant onto the first die with a first nozzle in the first compartment; and
opening a second valve on a first outlet pipe connected to the first compartment to remove the first liquid coolant.

20. The method of claim 17, further comprising moving the heat transfer structure towards the substrate to seal the first liquid coolant between the first compartment and the first die with a first removable seal and seal the second liquid coolant between the second compartment and the second die with a second removable seal.
